(19) United States
(12) Patent Application Publication
(10) Pub. No.: US 2007/0258214 A1
(43) Pub. Date: Nov. 8, 2007

(54) Heat-Dissipating Device with Tapered Fins

(76) Inventor: Yu-Nung Shen, Taipei (TW)

Correspondence Address: BANNER & WITCOFF, LTD., 1100 13th STREET, N.W., SUITE 1200, WASHINGTON, DC, 20005-4051, US

(21) Appl. No.: 11/744,378

(22) Filed: May 4, 2007

(30) Foreign Application Priority Data
May 8, 2006 (TW) 095207839

(51) Int. Cl. H05K 7/20

(52) U.S. Cl. 361/704; 361/718

(57) ABSTRACT

A heat-dissipating device includes a mounting seat and a plurality of tapered heat-dissipating fins. The mounting seat is made of a thermally conducting material, and has an inner side surface adapted to be in thermal contact with a heat source, and an outer side surface. The heat-dissipating fins extend from the outer side surface of the mounting seat in a direction away from the mounting seat. Each of the heat-dissipating fins has a proximate end proximate to the mounting seat, and a distal end distal from the mounting seat. The thickness of each of the heat-dissipating fins reduces gradually from the proximate end to the distal end. The distance between any two adjacent ones of the heat-dissipating fins increases gradually in the direction.

### CROSS-REFERENCE TO RELATED APPLICATION

This application claims priority of Taiwanese Application No. 095207839, filed on May 8, 2006.

### BACKGROUND OF THE INVENTION

1. Field of the Invention

This invention relates to a heat-dissipating device, and more particularly to a heat-dissipating device having a plurality of tapered heat-dissipating fins.

2. Description of the Related Art

Referring to FIG. 1, a heat-dissipating device primarily applied to a central processing unit (CPU) of a computer includes a mounting seat 1 and a plurality of parallel heat-dissipating fins 11 extending from a side surface 10 of the mounting seat 1. Any two adjacent heat-dissipating fins 11 define an air channel 111. Since the heat-dissipating fins 11 have a uniform thickness and are equally spaced apart, the air channels 111 have a uniform width. This makes it difficult to dissipate heat from the portions of the air channels 111 adjacent to the mounting seat 1.

### SUMMARY OF THE INVENTION

The object of this invention is to provide a heat-dissipating device with a plurality of heat-dissipating fins that are tapered so as to promote the heat-dissipating efficiency of the device.

According to this invention, a heat-dissipating device includes a mounting seat and a plurality of tapered heat-dissipating fins. The mounting seat is made of a thermally conducting material, and has an inner side surface adapted to be in thermal contact with a heat source, and an outer side surface. The heat-dissipating fins extend from the outer side surface of the mounting seat in a direction away from the mounting seat. Each of the heat-dissipating fins has a proximate end proximate to the mounting seat, and a distal end distal from the mounting seat. The thickness of each of the heat-dissipating fins reduces gradually from the proximate end to the distal end. The distance between any two adjacent ones of the heat-dissipating fins increases gradually in the direction.

### BRIEF DESCRIPTION OF THE DRAWINGS

These and other features and advantages of this invention will become apparent in the following detailed description of the preferred embodiments of this invention, with reference to the accompanying drawings, in which:

FIG. 1 is a perspective view of a conventional heat-dissipating device;

FIG. 2 is a perspective view of the first preferred embodiment of a heat-dissipating device according to this invention;

FIG. 3 is a fragmentary schematic view of the first preferred embodiment illustrating a portion of a cross section of the heat-dissipating device;

FIG. 4 is an exploded perspective view of the second preferred embodiment of a heat-dissipating device according to this invention; and

FIG. 5 is an assembled perspective view of the second preferred embodiment.

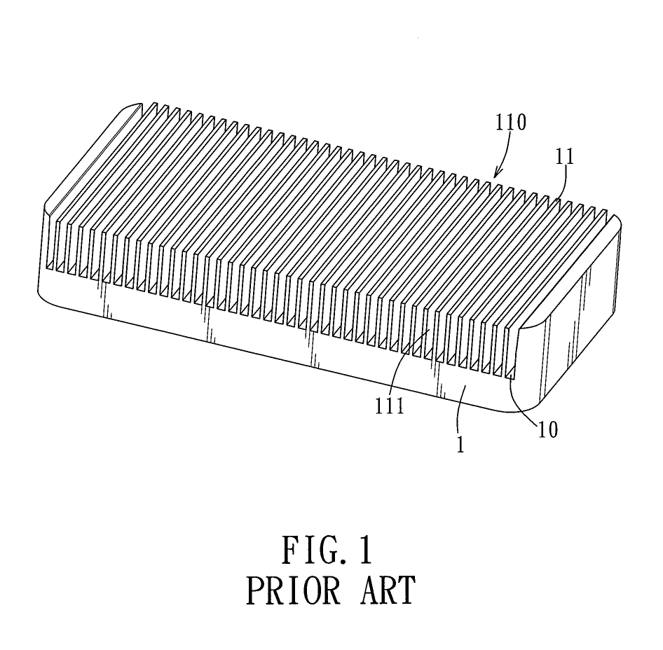

### DETAILED DESCRIPTION OF THE PREFERRED EMBODIMENTS

Before the present invention is described in greater detail in connection with the preferred embodiments, it should be noted that similar elements and structures are designated by like reference numerals throughout the entire disclosure.

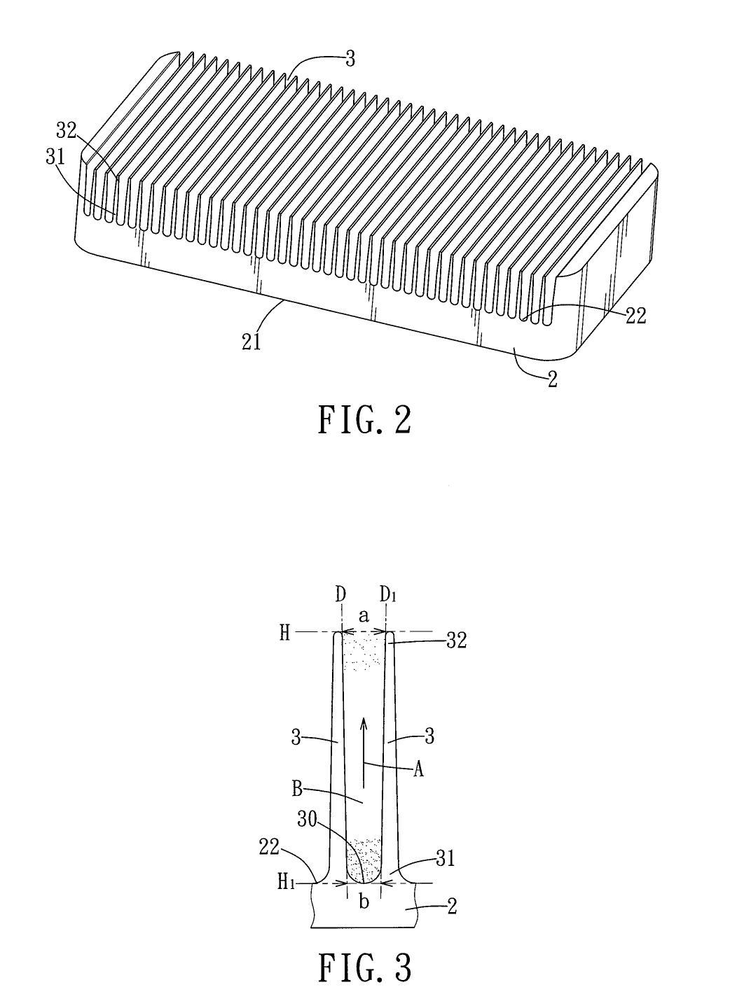

Referring to FIGS. 2 and 3, the first preferred embodiment of a heat-dissipating device according to this invention includes a mounting seat 2 and a plurality of heat-dissipating fins 3.

The mounting seat 2 is made of a thermally conducting material, such as aluminum, and has an inner side surface 21 in thermal contact with a heat source (e.g., a CPU of a computer), and an outer side surface 22 opposite to the inner side surface 21.

The heat-dissipating fins 3 extend from the outer side surface 22 of the mounting seat 2 in a direction (A) away from the mounting seat 2. Any two adjacent heat-dissipating fins 3 define an air channel (B) therebetween. Each of the heat-dissipating fins 3 has a proximate end 31 proximate to the mounting seat 2, and a distal end 32 distal from the mounting seat 2. The thickness of each of the heat-dissipating fins 3 reduces gradually from the proximate end 31 to the distal end 32. As such, the distance between any two adjacent heat-dissipating fins 3 increases gradually in the direction (A), thereby facilitating transmission of heat in the corresponding air channel (B) in the direction (A).

In this embodiment, the distal end 32 of each of the heat-dissipating fins 3 is rounded, and the proximate ends 31 of any two adjacent heat-dissipating fins 3 cooperate with the outer side surface 22 of the mounting seat 2 to define a curved slot 30.

In a cross section of the heat-dissipating device shown in FIG. 3, imaginary extension planes (D, D1) of two adjacent side surfaces of any two adjacent heat-dissipating fins 3 are spaced apart from each other along an upper line (H) extending along top ends of the two adjacent heat-dissipating fins 3 by a long distance (a), and along a lower line (H1) perpendicular to the direction (A) and extending through a lower end of the curved slot (30) defined by the proximate ends 31 of the two adjacent heat-dissipating fins 3 and the outer side surface 22 of the mounting seat 2 by a short distance (b). Based on experimentation, in order to obtain the best heat-dissipating effect, the ratio of the short distance (b) to the long distance (a) is preferably no greater than 0.75, and is optimally no greater than 0.5.

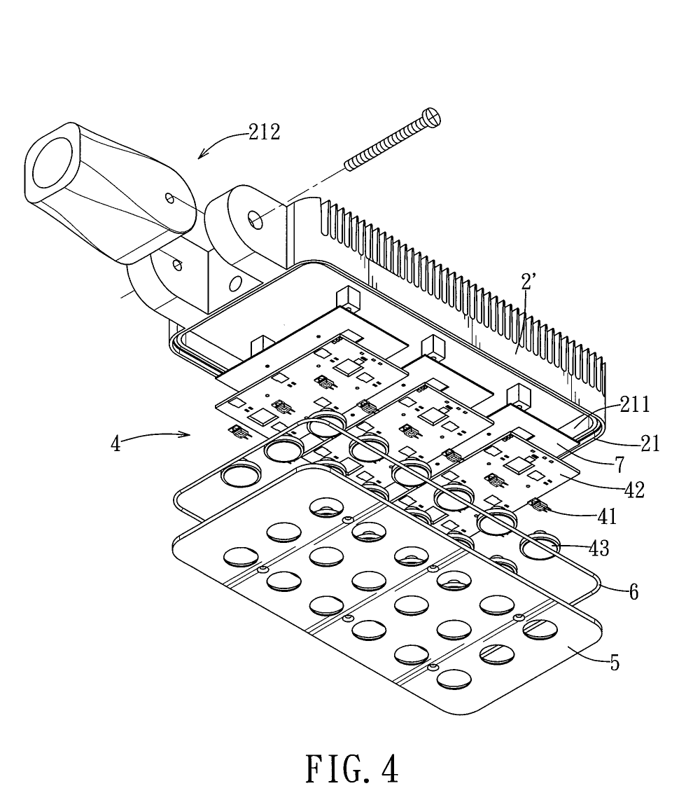

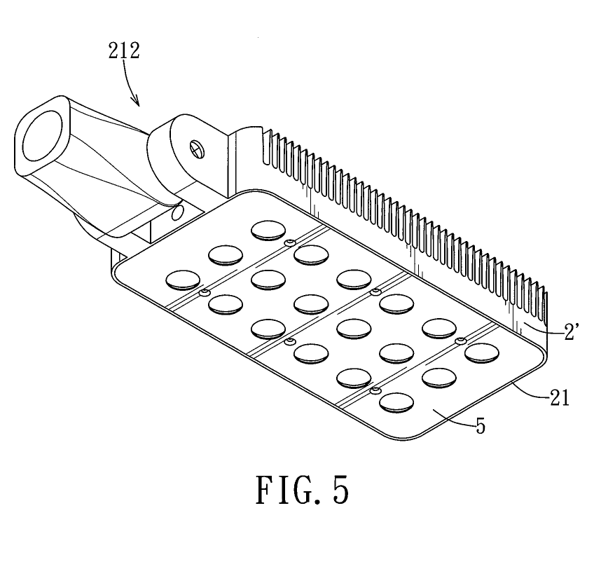

FIGS. 4 and 5 show the second preferred embodiment of a heat-dissipating device according to this invention, which includes a modified mounting seat 2′ and which is used for dissipating heat from a heat source 4. The heat source 4 serves as an illumination unit, and includes a plurality of light-emitting diode lamps 41, a circuit board unit electrically coupled to the light-emitting diode lamps 41 and consisting of a plurality of circuit boards 42, and a plurality of reflectors 43. The modified mounting seat 2′ includes a recess 211 formed in the inner side surface 21 for accommodating the heat source 4, and a knuckle member 212 disposed on a left side surface thereof. The heat-dissipating device further includes a cover plate 5 attached fixedly to the modified mounting seat 2′ for covering the recess 211, an annular water seal 6 disposed between the cover plate 5 and the modified mounting seat 2′ so as to establish a water-tight seal therebetween, and a graphite plate unit consisting of a plurality of graphite plates 7 each having two opposite side surfaces in thermal contact with the modified mounting seat 2′ and the circuit board unit, respectively. It is noted that when the heat source 4 is used indoors, the water seal 6 may not be necessary.

With this invention thus explained, it is apparent that numerous modifications and variations can be made without departing from the scope and spirit of this invention. It is therefore intended that this invention be limited only as indicated by the appended claims.

I claim:

1. A heat dissipating device comprising:
a mounting seat made of a thermally conducting material and having an inner side surface adapted to be in thermal contact with a heat source, and an outer side surface opposite to said inner side surface; and
a plurality of tapered heat-dissipating fins extending from said outer side surface of said mounting seat in a direction away from said mounting seat, each of said heat-dissipating fins having a proximate end proximate to said mounting seat, a distal end distal from said mounting seat, and a thickness reducing gradually from said proximate end to said distal end such that a distance between any two adjacent ones of said heat-dissipating fins increases gradually in the direction.

2. The heat dissipating device as claimed in claim 1, wherein said thermally conducting material is aluminum.

3. The heat dissipating device as claimed in claim 1, wherein said distal end of each of said heat-dissipating fins is rounded, and said proximate ends of any two adjacent ones of said heat-dissipating fins cooperate with said outer side surface of said mounting seat to define a curved slot thereamong.

4. The heat dissipating device as claimed in claim 3, wherein, in a cross section of said heat-dissipating device, imaginary extension planes of two adjacent side surfaces of any two adjacent ones of said heat-dissipating fins are spaced apart from each other along a line extending along top ends of said corresponding two adjacent ones of said heat-dissipating fins by a long distance, and along a line perpendicular to the direction and extending through a lower end of said curved slot defined by said proximate ends of said corresponding two adjacent ones of said heat-dissipating fins and said outer side surface of said mounting seat by a short distance, a ratio of said short distance to said long distance being no greater than 0.75.

5. The heat dissipating device as claimed in claim 4, wherein said ratio of said short distance to said long distance is no greater than 0.5.

6. The heat dissipating device as claimed in claim 1, the heat source includes a plurality of light-emitting diode lamps serving as an illumination unit, wherein said inner side surface of said mounting seat is formed with a recess adapted to accommodate the heat source.

7. The heat dissipating device as claimed in claim 6, further comprising a cover plate attached fixedly to said mounting seat for covering said recess.

8. The heat dissipating device as claimed in claim 7, further comprising an annular water seal disposed between said cover plate and said mounting seat so as to establish a water-tight seal therebetween.

9. The heat dissipating device as claimed in claim 6, the heat source further including a circuit board unit electrically coupled to the light-emitting diode lamps, wherein said heat-dissipating device further comprises at least one graphite plate having two opposite side surfaces adapted to be in thermal contact with the circuit board unit and said mounting seat, respectively.
